(19) United States
(12) Patent Application Publication
(10) Pub. No.: US 2026/0188361 A1
(43) Pub. Date: Jul. 2, 2026

(54) Clock Gating Circuitry

(71) Applicant: Micron Technology, Inc., Boise, ID (US)

(72) Inventor: Brynan Qiu, Dallas, TX (US)

(21) Appl. No.: 19/371,908

(22) Filed: Oct. 28, 2025

Related U.S. Application Data
(60) Provisional application No. 63/740,611, filed on Dec. 31, 2024.

(51) Int. Cl. G11C 7/10; G11C 7/22

(52) U.S. Cl. CPC G11C 7/1012; G11C 7/1063; G11C 7/222

(57) ABSTRACT

A memory device includes command path circuitry that includes shifting circuitry and exit stage circuitry. The shifting circuitry may shift a command signal according to a first clock or a second clock, and the exit stage circuitry may receive one or more control signals, generate one or more shifted signals based on the command signal and the first clock, and generate an output command signal based on the command signal, the one or more shifted signals, and one or more control signals.

### CROSS-REFERENCE TO RELATED APPLICATIONS

This application claims priority to U.S. Provisional Application No. 63/740,611, filed Dec. 31, 2024, which is incorporated by reference herein in its entirety.

### BACKGROUND OF THE INVENTION

### 1. Field of the Invention

The present invention relates generally to semiconductor devices. More specifically, embodiments of the present disclosure relate to clock gating for signals.

### 2. Description of the Related Art

A semiconductor device, such as a microcomputer, memory, gate array, among others, may include command paths to transmit commands from a command source, such as an input pin, register, controller, and the like, to logic in the semiconductor device configured to implement the command. The command paths may include digital circuits that may be used in the semiconductor device to facilitate implementing the command. In such a digital logic circuit, command data or signals are stored in memory elements, such as flip-flops, and changes in the states (e.g., toggling) of the memory elements are synchronized by a clock gating cell with logic gate(s) to generate a clock signal. For example, the output of a flip-flop is constant until a pulse is applied to its clock input, upon which the data at the input of the flip-flop is latched to its output.

Additionally, to account for functions of the semiconductor device that operate according to different clocking mechanisms, the clock signal may be phase-shifted by various degrees, and the phase-shifted clocks signals may be applied to the flip-flops at various points in the command path. However, maintaining and applying multiple clock signals for each clocking and switching event of the flip-flops may consume power. Accordingly, embodiments of the present disclosure may be directed to an improved command path that propagates fewer clock signals, especially when at least some of the clocks are unused during some of the time.

### BRIEF DESCRIPTION OF THE DRAWINGS

FIG. 1 is a simplified block diagram illustrating certain features of a memory device, in accordance with an embodiment;

FIG. 2 is a block diagram of command path circuitry in a command decoder of the memory device of FIG. 1, in accordance with an embodiment;

FIG. 3 is a block diagram of exit stage circuitry of the command path circuitry of FIG. 2 that generates an output command signal, in accordance with an embodiment;

FIG. 4 is a block diagram of clock generation circuitry of the command path circuitry of FIG. 2 that selectively generates one or more clock signals based on enable signals, in accordance with an embodiment;

FIG. 5 is a block diagram of shifting circuitry and selection circuitry of the exit stage circuitry of FIG. 2, in accordance with an embodiment; and

FIG. 6 is a flow chart of a method for generating an output command signal using a clock of a command signal, in accordance with an embodiment.

### DETAILED DESCRIPTION OF SPECIFIC EMBODIMENTS

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

As mentioned, a semiconductor device, such as a microcomputer, memory, gate array, among others, may include command paths to transmit commands from a command source, such as a host device, input pin, register, controller, and the like, to logic in the semiconductor device configured to implement the command. The command paths may include synchronous digital circuits that may be used in the semiconductor device to facilitate implementing the command. In a synchronous digital logic circuit, command data or signals are stored or latched in memory elements, such as flip-flops, and changes in the states (e.g., toggling) of the memory elements are synchronized by a clock gating cell with logic gate(s) to generate a clock signal. For example, the output of a flip-flop is constant until a pulse is applied to its clock input, upon which the data at the input of the flip-flop is latched to its output.

Some command path designs may include multiple shifter stages, each stage including multiple flip-flops that are chained together by connecting the output of one flip-flop to the input of another. Such a cascade of flip-flops may together form a shift register, in which a command signal may be stored in, and shifted between, the multiple flip-flops of the multiple stages. Further, the multiple flip-flops of a stage that carry command signals may be synchronized according to different clock signals. As such, each stage may be able to carry command signals on multiple command paths. For example, a first command path (e.g., an even command path) may include flip-flops of multiple shifter stages synchronized according to an unshifted clock signal, and a second command path (e.g., an odd command path) may include different flip-flops of the same shifter stages that are synchronized according to a 180-degree phase-shifted clock signal. A command signal may be stored and latched by either command path depending on when the command signal is received and which clock is used to capture the command signal.

The multiple command paths may share a common exit stage. The exit stage may receive a command signal from the even command path or the odd command path, and may include additional flip-flops, latches, inverters, OR gates, AND gates, or other logic gate circuitry that may manipulate the command signal to produce an output command signal. For example, the exit stage may receive a command signal from an even command path according to an unshifted clock signal and may extend the command signal by one cycle of an internal clock. To do so, the exit stage may use one or more clock signals, such as clock signal of the even command path (e.g., the unshifted clock) and/or the clock signal of the odd command path (180-degree phase-shifted clock). However, generating and using multiple clock signals for such manipulations of a command signal may consume power, especially when command signals are received in rapid succession. It may thus be advantageous to manipulate a command signal using the clock signal of the command path by which the command signal was received rather than the opposite clock signal.

Systems and methods described herein include command path circuitry that produces an output command signal based on a command signal and a command path clock signal. The command path circuitry may include stages of a command path, each stage including flip-flops that are synchronized according to one of multiple clock signals. The stages of the command path may store and latch a command signal on an even command path, in which the command signal is shifted according to an unshifted clock signal, or an odd command path, in which the command signal is shifted according to a 180-degree phase-shifted clock signal. The command path circuitry may also include an exit stage (e.g., exit stage circuitry) that manipulates a command signal to produce and output command signal. The exit stage may perform such manipulations using the clock signal of the command path. For example, if the command signal is received from an even command path, the exit stage may use an unshifted clock signal, and if the command signal is received from an odd command path, the exit stage may use a 180-degree phase-shifted clock signal.

To do so, the exit stage of the command path circuitry may provide the command signal and the clock signal to exit shift circuitry that may include a latch and a flip-flop in parallel. The exit shift circuitry may produce a 1-cycle shifted command signal using the latch and a 2-cycle shifted command signal using the flip-flop. The 1-cycle shifted command signal and the 2-cycle shifted command signal may be provided to selection circuitry of the exit stage. The selection circuitry may select, based on one or more control signals, the command signal, the 1-cycle shifted version of the command signal, and/or the 2-cycle shifted version of the command signal to produce a shifted command signal. The shifted command signal may be provided to additional shift circuitry of the exit stage, and the additional shift circuitry may shift the shifted command signal further based on one or more additional clock signals, such as a 90-degree phase-shifted clock signal and a 270-degree phase-shifted clock signal, to generate the output command signal. As such, to generate the output command signal, the exit stage may use the clock signal of the even command path or the odd command path (e.g., the unshifted clock signal or the 180-degree phase-shifted clock signal) and may not use both the clock signals of the even command path and the odd command path. The clock signal of the even or odd command path that is not used may be gated (i.e., at least partially not propagated), not generated, or otherwise suppressed, which may reduce power consumption.

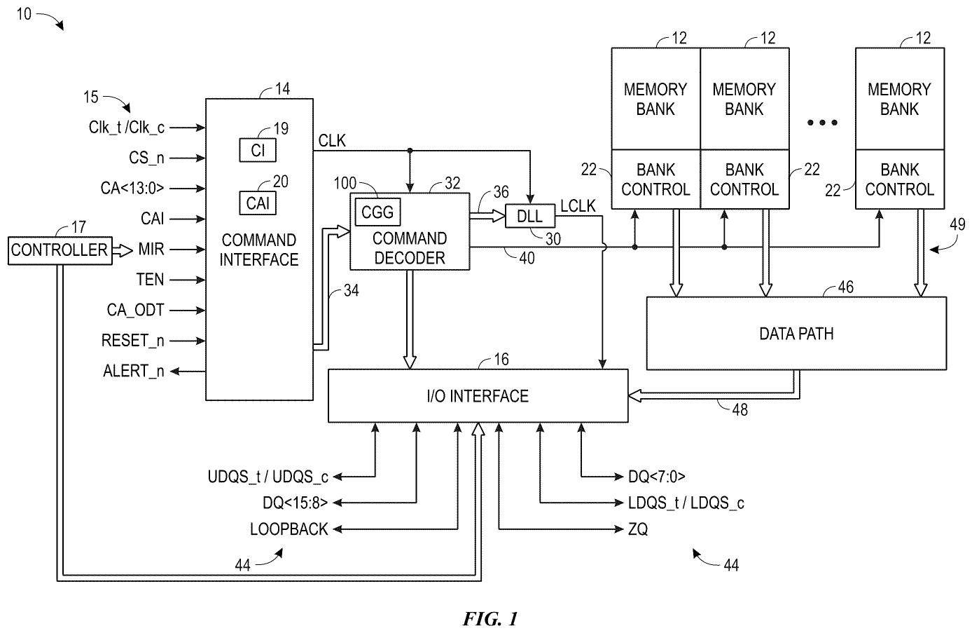

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a DDR5 SDRAM device. Various features of DDR5 SDRAM allow for reduced power consumption, more bandwidth and more storage capacity compared to prior generations of DDR SDRAM.

The memory device 10, may include a number of memory banks 12. The memory banks 12 may be DDR5 SDRAM memory banks, for instance. The memory banks 12 may be provided on one or more chips (e.g., SDRAM chips) that are arranged on dual inline memory modules (DIMMS). Each DIMM may include a number of SDRAM memory chips (e.g., x8 or x16 memory chips), as will be appreciated. Each SDRAM memory chip may include one or more memory banks 12. The memory device 10 represents a portion of a single memory chip (e.g., SDRAM chip) having a number of memory banks 12. For DDR5, the memory banks 12 may be further arranged to form bank groups. For instance, for an 8 gigabyte (Gb) DDR5 SDRAM, the memory chip may include 16 memory banks 12, arranged into 8 bank groups, each bank group including 2 memory banks. For a 16 Gb DDR5 SDRAM, the memory chip may include 32 memory banks 12, arranged into 8 bank groups, each bank group including 4 memory banks, for instance. Various other configurations, organizations, and sizes of the memory banks 12 on the memory device 10 may be utilized depending on the application and design of the overall system.

The memory device 10 may include a command interface 14 and an input/output (I/O) interface 16. The command interface 14 is configured to provide a number of signals (e.g., signals 15) from an external device, such as a processor or controller 17. The processor or controller 17 may provide various signals 15 (including the DQ signals) to the memory device 10 to facilitate the transmission and receipt of data to be written to or read from the memory device 10.

As will be appreciated, the command interface 14 may include a number of circuits, such as a clock input circuit 19 and a command address input circuit 20, for instance, to ensure proper handling of the signals 15. The command interface 14 may receive one or more clock signals from an external device. Generally, double data rate (DDR) memory utilizes a differential pair of system clock signals, referred to herein as the true clock signal (Clk_t) and the bar clock signal (Clk_c). The positive clock edge for DDR refers to the point where the rising true clock signal Clk_t crosses the falling bar clock signal Clk_c, while the negative clock edge indicates that transition of the falling true clock signal Clk_t and the rising of the bar clock signal Clk_c. Commands (e.g., read command, write command, etc.) are typically entered on the positive edges of the clock signal and data is transmitted or received on both the positive and negative clock edges.

The clock input circuit 19 receives the true clock signal (Clk_t) and the bar clock signal (Clk_c) and generates an internal clock signal CLK. The internal clock signal CLK is supplied to an internal clock generator, such as a delay locked loop (DLL) circuit 30. The DLL circuit 30 generates a phase controlled internal clock signal LCLK based on the received internal clock signal CLK. The phase controlled internal clock signal LCLK is supplied to the I/O interface 16, for instance, and is used as a timing signal for determining an output timing of read data.

The internal clock signal(s)/phases CLK may also be provided to various other components within the memory device 10 and may be used to generate various additional internal clock signals. For instance, the internal clock signal CLK may be provided to a command decoder 32. The command decoder 32 may receive command signals from the command bus 34 and may decode the command signals to provide various internal commands. For instance, the command decoder 32 may provide command signals to the DLL circuit 30 over the bus 36 to coordinate generation of the phase controlled internal clock signal LCLK. The phase controlled internal clock signal LCLK may be used to clock data through the IO interface 16, for instance. As will be appreciated, the command decoder 32 may include components, such as command path circuitry 33 coupled to the command bus 34 to facilitate the flow of signals and/or logical operations performed on those signals.

Further, the command decoder 32 may decode commands, such as read commands, write commands, mode-register set commands, activate commands, etc., and provide access to a particular memory bank 12 corresponding to the command, via the bus path 40. As will be appreciated, the memory device 10 may include various other decoders, such as row decoders and column decoders, to facilitate access to the memory banks 12. In one embodiment, each memory bank 12 includes a bank control block 22 which provides the necessary decoding (e.g., row decoder and column decoder), as well as other features, such as timing control and data control, to facilitate the execution of commands to and from the memory banks 12.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command interface may include a command address input circuit 20 which is configured to receive and transmit the commands to provide access to the memory banks 12, through the command decoder 32, for instance. In addition, the command interface 14 may receive a chip select signal (CS_n). The CS_n signal enables the memory device 10 to process commands on the incoming CA<13:0> bus. Access to specific banks 12 within the memory device 10 is encoded on the CA<13:0> bus with the commands.

In addition, the command interface 14 may be configured to receive a number of other command signals. For instance, a command/address on die termination (CA_ODT) signal may be provided to facilitate proper impedance matching within the memory device 10. A reset command (RESET_n) may be used to reset the command interface 14, status registers, state machines and the like, during power-up for instance. The command interface 14 may also receive a command/address invert (CAI) signal which may be provided to invert the state of command/address signals CA<13:0> on the command/address bus, for instance, depending on the command/address routing for the particular memory device 10. A mirror (MIR) signal may also be provided to facilitate a mirror function. The MIR signal may be used to multiplex signals so that they can be swapped for enabling certain routing of signals to the memory device 10, based on the configuration of multiple memory devices in a particular application. Various signals to facilitate testing of the memory device 10, such as the test enable (TEN) signal, may be provided, as well. For instance, the TEN signal may be used to place the memory device 10 into a test mode for connectivity testing.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity test mode executed using the TEN signal, as described above.

Data may be sent to and from the memory device 10, utilizing the command and clocking signals discussed above, by transmitting and receiving data signals 44 through the IO interface 16. More specifically, the data may be sent to or retrieved from the memory banks 12 over the datapath 46, which includes multiple bi-directional data buses. Data IO signals, generally referred to as DQ signals, are generally transmitted and received in one or more bi-directional data buses. The datapath 46 may convert the DQ signals from a serial bus 48 to a parallel bus 49.

For certain memory devices, such as a DDR5 SDRAM memory device, the IO signals may be divided into upper and lower bytes. For instance, for a x16 memory device, the IO signals may be divided into upper and lower IO signals (e.g., DQ<15:8> and DQ<7:0>) corresponding to upper and lower bytes of the data signals, for instance.

To allow for higher data rates within the memory device 10, certain memory devices, such as DDR memory devices may utilize data strobe signals, generally referred to as DQS signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the DQS signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance.

The DQS signals are driven by the controller 17 to the memory device 10 to strobe in write data. When the write operation is complete, the controller 17 will stop driving the DQS and allow it to float to an indeterminate tri-state condition. When the DQS signal is no longer driven by the controller 17, the external DQS signal from the controller 17 to the memory device 10 will be at an unknown/indeterminate state. This state can cause undesirable behavior inside the memory device 10 because an internal DQS signal inside the memory device 10 may be at an intermediate level and/or may oscillate. In some embodiments, even the external DQS signal may ring at the I/O interface 16 when the controller 17 stops driving the external DQS signal.

The DDR5 specification may include a short postamble period where the external DQS signal is still driven by the controller 17 after the last write data bit to allow time for disabling of write circuitry to propagate before the controller 17 ceases to drive the external DQS signal. The DDR5 specification may define a short (e.g., 0.5 tCK) postamble period and a long (e.g., 1.5 tCK) postamble period that may be selected using a mode register. However, the short postamble period may provide a short period of time to reset a DFE buffer.

Returning to FIG. 1, an impedance (ZQ) calibration signal may also be provided to the memory device 10 through the IO interface 16. The ZQ calibration signal may be provided to a reference pin and used to tune output drivers and ODT values by adjusting pull-up and pull-down resistors of the memory device 10 across changes in process, voltage, and temperature (PVT) values. Because PVT characteristics may impact the ZQ resistor values, the ZQ calibration signal may be provided to the ZQ reference pin to be used to adjust the resistance to calibrate the input impedance to known values. As will be appreciated, a precision resistor is generally coupled between the ZQ pin on the memory device 10 and GND/VSS external to the memory device 10. This resistor acts as a reference for adjusting internal ODT and drive strength of the IO pins.

In addition, a loopback signal (LOOPBACK) may be provided to the memory device 10 through the IO interface 16. The loopback signal may be used during a test or debugging phase to set the memory device 10 into a mode wherein signals are looped back through the memory device 10 through the same pin. For instance, the loopback signal may be used to set the memory device 10 to test the data output of the memory device 10. Loopback may include both a data and a strobe or possibly just a data pin. This is generally intended to be used to monitor the data captured by the memory device 10 at the IO interface 16.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the memory device 10), etc., may also be incorporated into the memory device 10. Accordingly, it should be understood that the block diagram of FIG. 1 is only provided to highlight certain functional features of the memory device 10 to aid in the subsequent detailed description.

DDR5 allows write operations to be performed consecutively such that data entry is gapless between two consecutive writes. In this case, the normal postamble for the first write operation and/or the normal preamble for the second write operation may be completely eliminated. For some consecutive write operations, there may be cycle gaps having a certain gap (e.g., 1, 2, 3, or more cycles) between the data burst of the first write operation and the data burst of the second write operation. For these cases, there may be a specified partial postamble and/or partial preamble to support these operations.

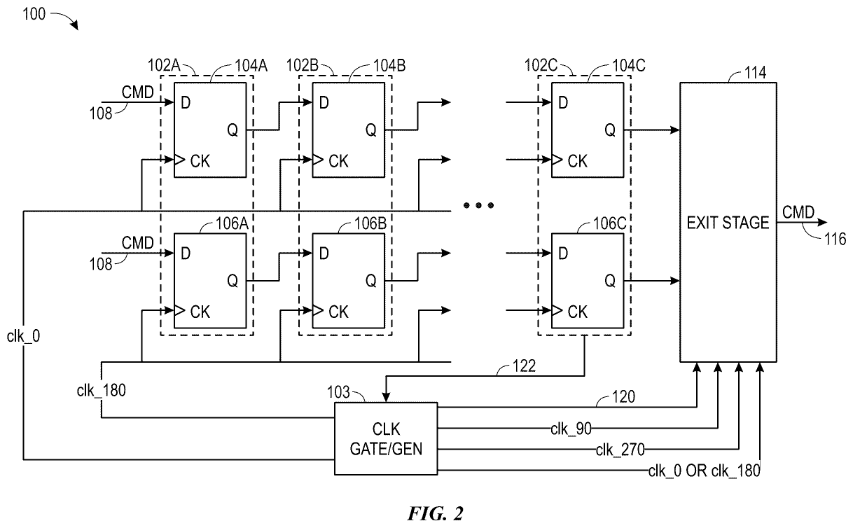

As set forth above, the command decoder 32 may include components, such as command path circuitry 100 coupled to the command bus 34 to facilitate the flow of signals and/or logical operations performed on those signals. FIG. 2 is an example block diagram of the command path circuitry 100 that carries a command signal 108. The command signal 108 may indicate a command for a memory device, such as a read command or write command. In some cases, the command signal 108 may correspond to an on-die termination command. The command path circuitry 100 may include numerous shifting stages (e.g., 60 or more shifting stages), here illustrated as shifting stages 102A, 102B, and 102C (collectively, “shifting stages 102”). Additionally, the command path circuitry 100 may include an exit stage 114, also referred to herein as exit stage circuitry 114. The command path circuitry 100 may also include clock gating and generation circuitry 103 that provides clock signals to the shifting stages 102 and the exit stage 114. The clock gating and generation circuitry 103 may represent, include, and/or be part of part of the circuitry of the memory device 10. For example, the clock gating and generation circuitry 103 may be part of the DLL circuit 30 of FIG. 1 (e.g., to generate clock signals clk_0, clk_90, clk_180, and clk_270) and/or the command decoder 32 (e.g., to generate control signals 120). Further, while an example of the command path circuitry 100 is shown for illustrative purposes as a single shifter with two paths, the command path circuitry 100 of the present embodiments may include additional paths for command signals, additional shifting stages, and/or additional exit stages, and the clock gating and generation circuitry 103 may selectively provide clock signals to those additional components.

Each of the shifting stages 102 may include one or more flip-flops that store and latch the command signal 108 based on a clk_0 signal or a clk_180 signal that each correspond to alternating clock cycles (e.g., odds and evens) of the clk. In the illustrated example, the shifting stages 102 respectively include a flip-flop 104A, a flip-flop 104B, and a flip-flop 104C (collectively, “flip-flops 104”) that store and latch the command signal 108 based on a clk_0 signal, which may include an unshifted clock signal (e.g., 0°-shifted clock signal, in-phase clock signal) and that may be provided by the clock gating and generation circuitry 103. The clk_0 signal may be based on the internal clock signal LCLK of FIG. 1. For example, the clk_0 signal may be unshifted relative to the internal clock signal LCLK and have half a frequency of the internal clock signal LCLK. The flip-flops 104 and the connections between them may be referred to herein as an even command path that propagates command signals captured with even clock cycles of a clock (e.g., the clk_0 signal).

Further, the shifting stages 102 include a flip-flop 106A, a flip-flop 106B, and a flip-flop 106C (collectively, “flip-flops 106”) that store and latch the command signal based on a clk_180 signal. The clk_180 signal is provided by the clock gating and generation circuitry 103 and may include a 180°-shifted version of the internal clock signal LCLK of FIG. 1. The flip-flops 106 and the connections between them may be referred to as an odd command path that propagates command signals captured with odd clock cycles of the clock (e.g., the clk_0 signal).

As illustrated, each of the flip-flops 104 and the flip-flops 106 may include an input pin D, an output pin Q, and a clock pin CK that may be used to store and latch the command signal. For example, an output pin Q of the flip-flop 104A is connected to an input pin D of the flip-flop 104B and, as such, the clk_0 signal may cause the command signal 108 to move (“shift”) from the flip-flop 104A to the flip-flop 104B. As the clk_0 and the clk_180 may correspond to every other cycle of the CLK, the flip-flops 104 may be used for one set (e.g., odd cycles or even) cycles while the flip-flops 106 are used for the other set of cycles. As such, the flip-flops 104, and the connections between them, may be part of an even command path (e.g., even pipeline) for shifting commands based on even cycles. The flip-flops 106, and the connections between them, may be part of an odd command path (e.g., odd pipelines) for shifting commands based on odd cycles.

The exit stage 114 may receive the command signal 108 from the shifting stage 102C. The exit stage 114 may include additional flip-flops, latches, invertors, OR gates, AND gates, or other logic gate circuitry that may manipulate the command signal 108 to produce an output command signal 116. For example, the exit stage 114 may shift and/or extend the command signal 108 to produce the output command signal 116, which may be better suited for use by other components than the command signal 108. However, to perform such shifts and extensions of the command signal 108, the exit stage may use different clock signals than those used by the shifting stages 102. In the illustrated example, the exit stage 114 may use a clk_90 signal and a clk_270 signal, which may include 90°-shifted version a 270°-shifted version of the internal clock signal LCLK of FIG. 1, respectively. For example, the exit stage 114 may use the clk_90 signal and the clk_270 signal to shift and/or extend the command signal 108 by 90° or 270° increments of an internal clock signal. For example, the clk_90 may correspond to an opposite edge (e.g., falling edge) of an edge (e.g., rising edge) of a same pulse the corresponds to the clk_0. Likewise, the clk_270 may correspond to the clk_180.

Further, the exit stage 114 may shift and/or extend the command signal 108 by an increment that corresponds to an opposite clock cycle of the command path from which the command signal 108 was received. For example, the exit stage 114 may receive a command signal from the even command path (e.g., using the clk_0 signal) but may shift the command signal 108 by 180 degrees (e.g., which may correspond to a one-cycle shift of the internal clock LCLK). However, generating the clk_180 for such a shift may consume power. Thus, selectively generating and/or propagating either the clk_0 signal or the clk_180 signal may enable a reduction in power consumption by the clock gating and generation circuitry 103 over generating and propagating both clock signals.

Accordingly, the clock gating and generation circuitry 103 may receive one or more busy signals 122 from one or more of the shifting stages 102 and, based on the busy signals 122, may determine whether to generate the clk_0 signal and clk_180 signal. The busy signals 122 may be generated by the shifting stages 102 based on a determination that flip-flops of the shifting stages 102 are busy in that they are storing and latching the command signal 108. Further, the busy signals 122 may indicate whether the command signal 108 is being shifted on the even command path or the odd command path. For example, each of the shifting stages 102 may determine whether a command signal is being stored and latched by the flip-flops 104 or the flip-flops 106. If the command signal 108 is being stored and latched by the flip-flops 104, the shifting stages 102 may cause the busy signals 122 to indicate that the command signal 108 is on the even command path. If the command signal 108 is being stored and latched by the flip-flops 106, the shifting stages 102 may cause the busy signals 122 to indicate that the command signal 108 is on the odd command path. Based on the one or more busy signals 122, the clock gating and generation circuitry 103 may generate one or more control signals 120 that cause the exit stage 114 to generate a desired output command signal 116 from the selected clock signal(s). As such, the exit stage 114 may generate the output command signal 116 based on the control signals 120.

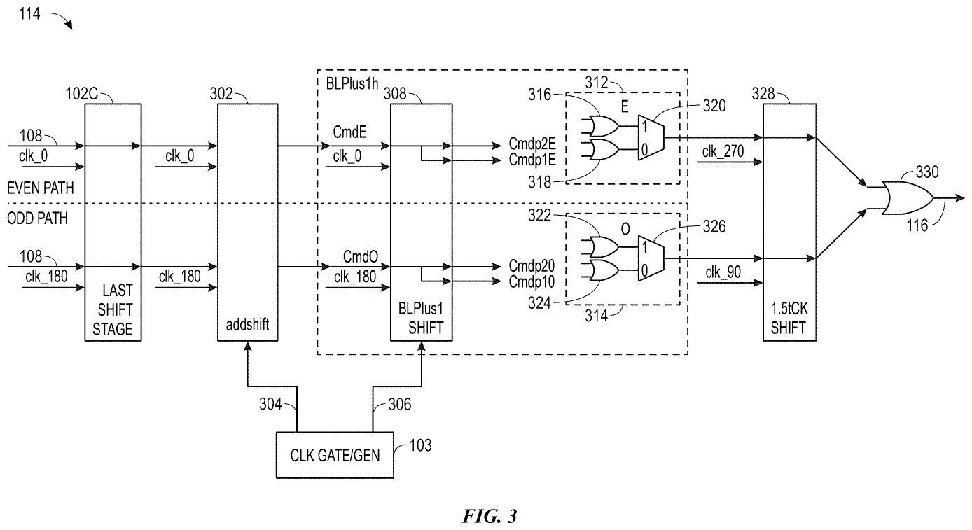

FIG. 3 is a block diagram of an example of the exit stage 114 that receives the command signal 108 from the shifting stage 102C (e.g., a last shifting stage) and generates the output command signal 116 based on the control signals 120. In the illustrated example, the exit stage 114 receives the command signal on the even command path or the odd command path and applies, at an addshift stage 302, a shift to the command signal 108 based on the clock signal of the even or odd command path and an addshift control signal 304 (e.g., a shift control signal) of the control signals 120. For example, if the command signal 108 is received from the even command path and the addshift control signal 304 is asserted, the addshift stage 302 may apply a shift to the command signal 108 based on the clk_0 received from the clock gating and generation circuitry 103, which may shift the command signal 108 from even to odd. If the command signal 108 is received from the odd command path and the addshift control signal 304 is asserted, the addshift stage 302 may apply a shift to the command signal 108 based on the clk_180 received from the clock gating and generation circuitry 120, which may shift the command signal 108 from odd to even. If the addshift control signal 304 is not asserted, the addshift stage may not apply a shift to the command signal 108.

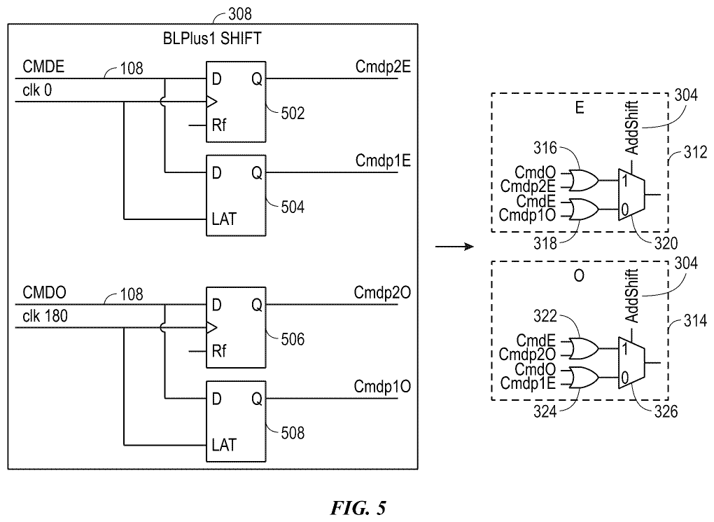

The shifted command signal 108 may be provided to Plus1 circuitry 308 that may generate shifted command signals Cmdp2E, Cmdp1E, Cmdp2O, and Cmdp1O based on the clock signal of the even or odd command path and a Plus1 control signal 306 of the control signals 120. The Cmdp2E may include a 2-cycle shifted version of the command signal if the command signal 108 is received on the even command path (and may be unasserted if the command signal 108 is received on the odd command path). The Cmdp1E may include a 1-cycle shifted version of the command signal if the command signal 108 is received on the even command path and may be unasserted otherwise. Similarly, the Cmdp2O may include a 2-cycle shifted version of the command signal if the command signal 108 is received on the odd command path and may be unasserted otherwise. Finally, the Cmdp1O may include a 1-cycle shifted version of the command signal if the command signal 108 is received on the odd command path and may be unasserted otherwise. As discussed below in reference to FIG. 5, the Plus1 circuitry 308 may include a first latch and flip-flop arrangement to generate the Cmdp2E and Cmdp1E and a second latch and flip-flop arrangement to generate the Cmdp2O and the Cmdp1O. Further, if the Plus1 control signal 306 is unasserted, the command signal 108 may be provided directly to even selection circuitry 312 and/or odd selection circuitry 314 and/or the Plus1 circuitry 308 may not assert each of the Cmdp2E, Cmdp1E, Cmdp2O, and Cmdp1O.

The shifted command signals Cmdp2E, Cmdp1E, Cmdp2O, and Cmdp1O may be provided to even selection circuitry 312 and/or odd selection circuitry 314. As illustrated, the even selection circuitry 312 includes OR gates 316 and 318 and a multiplexer 320. Likewise, the odd selection circuitry 314 may include OR gates 322 and 324 and a multiplexer 326. While not shown, the multiplexers 320 and 326 may receive, as selection inputs, the addshift control signal 304 to cause the multiplexer 320 to select between outputs of the OR gates 316 and 318 and to cause the multiplexer 326 to select between outputs of the OR gates 322, 324.

The outputs of the multiplexers 320 and 326 may be provided to a final shifting stage 328 (e.g., additional shifting circuitry). The final shifting stage 328 may shift the output of the multiplexers 320 and 326 based on the clk_90 signal and/or the clk_270 signal, as shown, which may cause a 1.5-cycle shift in the output of the multiplexers 320 and 326. For example, if the command signal 108 is received on the even command path, the final shifting stage 328 may apply a 1.5-cycle shift to a command signal 108 using the clk_270 signal. If the command signal is received on the odd command path, the final shifting stage 328 may apply a 1.5-cycle shift to a command signal 108 using the clk_90 signal. The output of the final shifting stage 328 may be provided to an OR gate 330 to generate the output command signal 116.

As mentioned, the exit stage 114 may generate the output command signal 116 based on the addshift control signal 304 and the Plus1 control signal 306. The addshift control signal 304 may determine whether the output command signal 116 is even or odd. Further, the Plus1 circuitry 308 may determine which signals are provided to the selection circuitry 312 and 314 based on the Plus1 control signal 306, which may cause a change in the output command signal 116. For example, the Plus1 circuitry 308 and the selection circuitry 312 and 314 may, based on the Plus1 control signal 306, extend the output command signal 116 such that the rising of the output command signal 116 is unchanged and the falling edge of the output command signal 116 is shifted by 1 cycle of the internal clock LCLK. For example, if the addshift control signal 304 is asserted and command signal 108 is even, the output command signal 116 may be odd. If, in the same example, the Plus1 control signal 306 is asserted, the output command signal 116 may be odd and extended by one clock cycle.

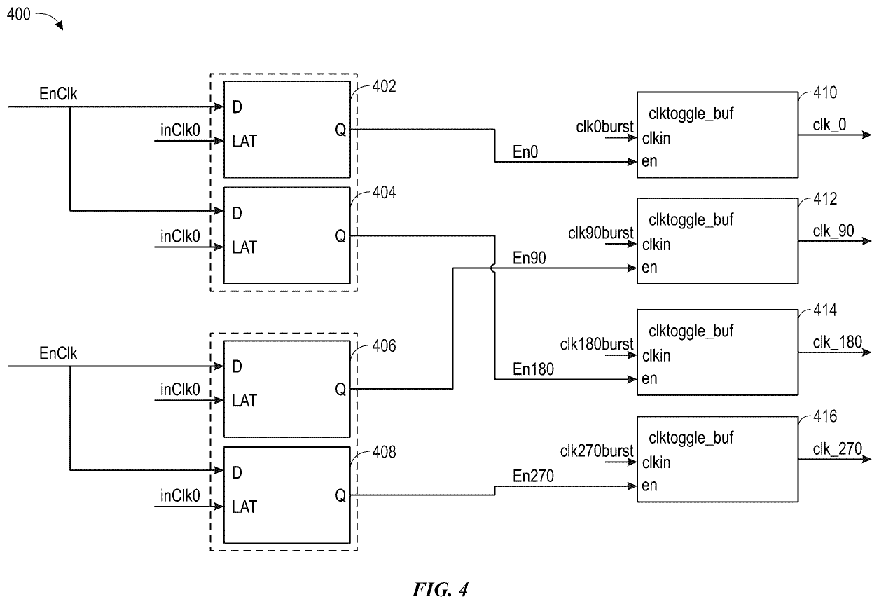

FIG. 4 is a block diagram of clock generation circuitry 400 that may selectively generate one or more clock signals, here illustrated as the clk_0 signal, the clk_90 signal, the clk_180 signal, and the clk_270 signal, based on one or more enable signals, here illustrated as the EnClk0 signal, the EnClk90 signal, the EnClk180 signal, and the EnClk270 signal. The clock generation circuitry 400 may be included as part of the clock gating and generation circuitry 103 of FIG. 2. For example, the EnClk0 and EnClk180 signals may be generated by the clock gating and generation circuitry 103 based on the one or more busy signals 122 that indicate whether the command signal 108 is on the even command path or the odd command path. As such, the clock generation circuitry 400 may generate or not generate (e.g., suppress) the clk_0 and clk_180 signals based on the one or more busy signals 122. Additionally or alternatively, the clock generation circuitry 400 may generate all clock signals but may suppress propagation of at least one of the clocks at least some of the time.

As illustrated, the clock generation circuitry 400 includes latches 402, 404, 406, and 408 that generate respective enable signals En0, En90, En180, and En270 based on the EnClk0 signal, the EnClk90 signal, the EnClk180 signal, or the EnClk270 signal. Each of the latches may include an input pin D, an output pin Q, and a latch pin LAT that may be used to store an input signal. For example, the latch 402 generates the En0 signal as the EnClk0 signal according to an inClk0 input clock signal, and the latch 404 generates the En180 signal as the EnClk180 signal according to an inClk180 input clock signal. Similarly, the latch 406 generates the En90 signal as the EnClk90 signal according to the inClk90 input clock signal, and the latch 408 generates the En270 signal as the EnClk270 signal according to the inClk270 input clock signal.

Each of the enable signals En0, En90, En180, and En270 may be provided to respective buffers 410, 412, 414, and 416. In the illustrated example, the buffer 410 may generate the clk_0 signal based on the En0 signal (e.g., when the En0 signal is high) and an input clk0burst signal derived from the CLK. Likewise, the buffer 412 may generate the clk_90 signal based on the En90 signal and an input clk90burst signal derived from the CLK, the buffer 414 may generate the clk_180 signal based on the En180 signal and an input clk180burst signal derived from the CLK, and the buffer 416 may generate the clk_270 signal based on the En270 signal and an input clk270burst signal derived from the CLK. As such, each of the clock signals clk_0, clk_90, clk_180, and clk_270 may be generated based on separate enable signals. This may be advantageous, as each clock signal may be used at different times according to, for example, whether the command signal 108 is even or odd. For an even command signal 108, for instance, the clk_0 signal may be enabled and the clk_180 disabled.

FIG. 5 is a block diagram of a portion of the exit stage 114, including the Plus1 circuitry 308, the even selection circuitry 312, and the odd selection circuitry 314. As shown, the Plus1 circuitry 308 may include a flip-flop 502 and a latch 504 that may receive command signals 108A on the even command path and a flip-flop 506 and a latch 508 that may receive command signals 108B on the odd command path. Collectively, the command signals when received via either the odd or even path are referred to as command signals 108. As mentioned, if the Plus1 control signal 306 is asserted, the Plus1 circuitry 308 may generate the Cmdp2E, Cmdp1E, Cmdp2O, and/or Cmdp1O signals based on the clock signal of the even or odd command path and a Plus1 control signal 306 of the control signals 120. If the Plus1 control signal 306 is not asserted, however, the command signal 108 may be provided directly to the even selection circuitry 312 and/or the odd selection circuitry 314.

As mentioned, the Cmdp2E may include a 2-cycle shifted version of the command signal 108 if the command signal 108 is received on the even command path. To generate the Cmdp2E signal, the flip-flop 502 may receive the command signal 108 at an input pin D and may receive clk_0 at a clock pin. As such, the Cmdp2E signal may be generated at an output pin Q as a 2-cycle shifted version of the command signal 108. If the command signal 108 is instead received at the odd command path, the input D may be unasserted (e.g., low) and, as such, the Cmdp2E signal may not be asserted if the command signal 108 is odd.

Similarly, to generate the Cmdp1E signal, the latch 504 may receive the command signal 108 at an input pin D and may receive the clk_0 signal at a latch pin LAT that may be used to store an input signal. As such, the latch 504 may generate the Cmdp1E signal as a 1-cycle shifted version of the command signal 108 if the command signal 108 is received on the even path. If the command signal 108 is instead received at the odd command path, the input D may be unasserted and, as such, the Cmdp1E signal may not be asserted if the command signal 108 is odd. Further, if the command signal 108 is received at the odd path, the clk_0 may not be generated by the clock gating and generation circuitry 103, which may reduce power consumption.

As discussed, the Cmdp2O signal may include a 2-cycle shifted version of the command signal if the command signal 108 is received on the odd command path. To generate the Cmdp2O signal, a flip-flop 506 may receive the command signal 108 at an input pin D and may receive the clk_180 signal at a clock pin. As such, the Cmdp2O signal may be generated at an output pin Q as a 2-cycle shifted version of the command signal 108. If the command signal 108 is instead received at the even command path, the input D may be unasserted (e.g., low) and, as such, the Cmdp2O signal may not be asserted if the command signal 108 is even.

To generate the Cmdp1O signal, the latch 508 may receive the command signal 108 at an input pin D and may receive the clk_180 signal at a latch pin LAT that may be used to store an input signal. As such, the latch 508 may generate the Cmdp1O signal as a 1-cycle shifted version of the command signal 108 if the command signal 108 is received on the odd path. If the command signal 108 is instead received at the even command path, the input D may be unasserted and, as such, the Cmdp1O signal may not be asserted if the command signal 108 is even. Further, if the command signal 108 is received at the even path, the clk_0 may not be generated by the clock gating and generation circuitry 103, which may reduce power consumption.

As shown, the Cmdp2E, Cmdp1E, Cmdp2O, and Cmdp1O signals may be provided, as input, to the OR gates 316, 318, 322, and 324. As part of the even selection circuitry 312, the OR gate 316 may receive a CmdO signal, which represents the command signal 108 on the odd command path, and the Cmdp2E signal. As may be appreciated, if the command signal 108 is on the even path, the CmdO may be low or not asserted. As such, the output of the OR gate 316 may be the command signal 108 if the command signal 108 is on the odd path, and may be the Cmdp2E signal if the command signal is on the even command path.

The OR gate 318 may receive a CmdE signal, which may represent the command signal 108 on the even command path, and the Cmdp1O signal. As may be appreciated, if the command signal 108 is on the odd command path, the CmdE may be low or not asserted. As such, the output of the OR gate 316 may be the command signal 108 if the command signal 108 is on the even path or may be the Cmdp1O signal if the command signal is on the odd command path.

The multiplexer 320 may select between the output of the OR gate 316 and the output of the OR gate 318 based on the addshift control signal 304. For example, if the addshift control signal 304 is asserted, the output of the multiplexer 320 may be the command signal 108 (e.g., if the command signal 108 is on the odd path) or the Cmdp2E signal (e.g., if the command signal is on the even path). If the addshift control signal 304 is not asserted, the output of the multiplexer 320 may be the command signal 108 (e.g., if the command signal 108 is on the even path) or the Cmdp1O signal (e.g., if the command signal is on the odd command path).

Moving on to the odd selection circuitry 314, the OR gate 322 may receive the CmdE signal and the Cmdp2E signal. As may be appreciated, if the command signal 108 is on the odd path, the CmdE may be low or not asserted. As such, the output of the OR gate 316 may be the command signal 108 if the command signal 108 is on the even path or the Cmdp2O signal if the command signal is on the odd command path.

The OR gate 324 may receive the CmdO signal and the Cmdp1E signal. As may be appreciated, if the command signal 108 is on the even path, the CmdO may be low or not asserted. As such, the output of the OR gate 316 may be the command signal 108 if the command signal 108 is on the odd path or the Cmdp1E signal if the command signal is on the even command path.

The multiplexer 326 may select between the output of the OR gate 322 and the output of the OR gate 324 based on the addshift control signal 304. For example, if the addshift control signal 304 is asserted, the output of the multiplexer 326 may be the command signal 108 (e.g., if the command signal 108 is on the even path) or the Cmdp2O signal (e.g., if the command signal is on the odd path). If the addshift control signal 304 is not asserted, the output of the multiplexer 320 may be the command signal 108 (e.g., if the command signal 108 is on the odd path) or the Cmdp1E signal (e.g., if the command signal is on the even command path). As shown in FIG. 3, the outputs of the multiplexers 320 and 326 may each be provided to the final shifting stage 328, and the outputs of the final shifting stage 328 may be provided to the OR gate 330 to produce the output command signal 116.

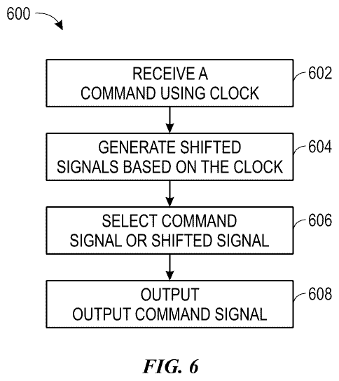

FIG. 6 is a flow chart of a method 600 for generating an output command signal (e.g., the output command signal 116) using a clock of an input command signal (e.g., the command signal 108). The method 600 may be performed by the command path circuitry 100 (e.g., by the exit stage 114 and the clock gating and generation circuitry 103). In block 602, the method 600 may begin with receiving the command signal 108 at the exit stage 114 from the shifting stage 102C using a clock. The clock may be one of multiple clocks based on a command path from which the command signal 108 is received. For example, if the command signal 108 is received from an even command path, the clock may be an unshifted clock that is based on an internal clock LCLK. If the command signal 108 is received from an odd command path, the clock may be a 180-degree phase-shifted clock based on the internal clock LCLK. Further, the clock gating and generation circuitry 103 may not generate any clocks that are not the clock of the command signal. For example, if the command signal 108 is received from the even command path, the clock gating and generation circuitry 103 may not generate the 180-degree phase-shifted clock, and if the command signal is received from the odd command path, the clock gating and generation circuitry 103 may not generate and/or propagate the unshifted clock.

In block 604, the method 600 may continue with the Plus1 circuitry 308 generating one or more shifted signals based on the clock. As described herein, the Plus1 circuitry 308 may include a flip-flop 502 and a latch 504 that may receive command signals 108 on the even command path and a flip-flop 506 and a latch 508 that may receive command signals 108 on the odd command path. As mentioned, if the Plus1 control signal 306 is asserted, the Plus1 circuitry 308 may generate the Cmdp2E, Cmdp1E, Cmdp2O, and/or Cmdp1O signals based on the clock signal of the even or odd command path and a Plus1 control signal 306. If the Plus1 control signal 306 is not asserted, however, the command signal 108 may be provided directly to the even selection circuitry 312 and/or the odd selection circuitry 314 (e.g., block 604 may be omitted).

In block 606, the even selection circuitry 312 and the odd selection circuitry 314 may select the command signal and/or the one or more shifted signals. As described herein, multiplexers 320 of the 326 of the even selection circuitry 312 and the odd selection circuitry 314 may select combinations of the CmdO, CmdE, Cmdp2E, Cmdp1E, Cmdp2O, and/or Cmdp1O signals based on the addshift control signal 304. For example, if the addshift control signal 304 is asserted, the output of the multiplexer 320 may be the command signal 108 (e.g., if the command signal 108 is on the odd path) or the Cmdp2E signal (e.g., if the command signal is on the even path). If the addshift control signal 304 is not asserted, the output of the multiplexer 320 may be the command signal 108 (e.g., if the command signal 108 is on the even path) or the Cmdp1O signal (e.g., if the command signal is on the odd command path). If the addshift control signal 304 is asserted, the output of the multiplexer 326 may be the command signal 108 (e.g., if the command signal 108 is on the even path) or the Cmdp2O signal (e.g., if the command signal is on the odd path). If the addshift control signal 304 is not asserted, the output of the multiplexer 320 may be the command signal 108 (e.g., if the command signal 108 is on the odd path) or the Cmdp1E signal (e.g., if the command signal is on the even command path).

In block 608, the exit stage 114 may output the output command signal 116. As shown in FIG. 3, the outputs of the multiplexers 320 and 326 may each be provided to the final shifting stage 328, and the outputs of the final shifting stage 328 may be provided to the OR gate 330 to produce the output command signal 116. As mentioned, the exit stage 114 may generate the output command signal 116 based on the addshift control signal 304 and the Plus1 control signal 306. The addshift control signal 304 may determine whether the output command signal 116 is even or odd. Further, the Plus1 control signal 306 may determine whether the output command signal 116 is extended by 1 cycle of the internal clock LCLK. For example, if the addshift control signal 304 is asserted and command signal 108 is even, the output command signal 116 may be odd. If, in the same example, the Plus1 control signal 306 is asserted, the output command signal 116 may be odd and extended by one clock cycle. Further, to generate and output the output command signal, the exit stage 114 may not use any clocks that are not the clock of the command signal. As such, the clock gating and generation circuitry 103 may not generate (e.g., may suppress) any clocks that are not the clock of the command signal, which may reduce power consumption.

What is claimed is:

1. A memory device, comprising:
command path circuitry comprising:
shifting circuitry configured to:
shift a command signal according to a first clock or a second clock; and
exit stage circuitry configured to:
receive one or more control signals;
generate one or more shifted signals based on the command signal and the first clock; and
generate an output command signal based on the command signal, the one or more shifted signals, and one or more control signals.

2. The memory device of claim 1, wherein the shifting circuitry is configured to generate, based on the command signal being shifted according to the first clock, one or more busy signals that indicate the first clock, and comprising clock gating and generation circuitry configured to:
receive the one or more busy signals;
generate the one or more control signals based on the one or more busy signals; and
transmit the one or more control signals to the exit stage circuitry.

3. The memory device of claim 2, wherein the clock gating and generation circuitry is configured to suppress generation or propagation of the second clock based on the one or more busy signals.

4. The memory device of claim 1, wherein the exit stage circuitry comprises one or more latches and one or more flip-flops configured to generate the one or more shifted signals based on the command signal and the first clock.

5. The memory device of claim 1, wherein the exit stage circuitry comprises one or more multiplexers configured to generate the output command signal based on the command signal, the one or more shifted signals, and one or more control signals.

6. The memory device of claim 1, wherein the exit stage circuitry comprises additional shifting circuitry configured to shift the output command signal based on a third clock, a fourth clock, or both.

7. The memory device of claim 1, wherein the one or more shifted signals comprise a first signal and a second signal, the first signal comprising the command signal shifted by one cycle of the first clock, and the second signal comprising the command signal shifted by two cycles of the first clock.

8. The memory device of claim 1, wherein the first clock is in-phase with a clock signal of the memory device.

9. The memory device of claim 1, wherein the first clock is phase-shifted by 180 degrees of a clock signal of the memory device.

10. A method, comprising;
receiving a command signal using a command path clock signal of one or more clock signals;
receiving one or more control signals;
generating one or more shifted signals based on the command path clock signal and the command signal;
generating an output command signal based on selecting the one or more shifted signals, the command signal, or both based on the one or more control signals; and
outputting the output command signal.

11. The method of claim 10, wherein the one or more control signals comprise a shift control signal, and comprising shifting, based on the shift control signal, the command signal.

12. The method of claim 11, wherein generating the output command signal based on selecting the one or more shifted signals, the command signal, or both based on the one or more control signals comprises providing the shift control signal as a selection input to one or more multiplexers configured to select between the one or more shifted signals, the command signal, or both.

13. The method of claim 10, comprising shifting the output command signal based on a second clock signal and a third clock signal.

14. The method of claim 13, wherein each of the one or more clock signals, the second clock signal, and the third clock signal comprises phase-shifted clock signals that are generated based on an internal clock signal of a memory device.

15. The method of claim 10, comprising suppressing generation or propagation of the one or more clock signals that are not the command path clock signal.

16. The method of claim 10, wherein the one or more shifted signals comprise a first signal and a second signal, the first signal comprising the command signal shifted by one cycle of the command path clock signal, and the second signal comprising the command signal shifted by two cycles of the command path clock signal.

17. A memory device, comprising:
shifting circuitry comprising an even command path and an odd command path, and configured to shift a command signal on the even command path or the odd command path; and
exit stage circuitry configured to:
receive the command signal from the even command path or the odd command path;
generate one or more shifted signals based on the command signal and a first clock signal of the even command path or a second clock signal of the odd command path; and
generate an output command signal based on the command signal and the one or more shifted signals.

18. The memory device of claim 17, wherein the even command path is configured to shift the command signal according to a first clock signal, and wherein the odd command path is configured to shift the command signal according to a second clock signal.

19. The memory device of claim 18, wherein the shifting circuitry is configured to generate one or more busy signals that indicate whether the command signal is being shifted on the even command path or the odd command path, and comprising clock gating and generation circuitry configured to:
receive the one or more busy signals;
based on the one or more busy signals indicating that the command signal is being shifted on the even command path:
suppress generation or propagation of the second clock signal
generate the first clock signal; and
transmit the first clock signal to the exit stage circuitry; and
based on the one or more busy signals indicating that the command signal is being shifted on the odd command path:
suppress generation or propagation of the first clock signal
generate the second clock signal; and
transmit the second clock signal to the exit stage circuitry.

20. The memory device of claim 17, wherein the exit stage circuitry is configured to:
receive one or more control signals; and
generate the output command signal based on the command signal, the one or more shifted signals, and the one or more control signals.
